(19) United States
(12) Patent Application Publication
(10) Pub. No.: US 2007/0045102 A1
(43) Pub. Date: Mar. 1, 2007

(54) Method of sputter depositing an alloy on a substrate

(75) Inventors: Chih-Ling Lee, Glen Cove, NY (US); Adrian Devasahayam, Commack, NY (US); Ming Mao, Pleasanton, CA (US); Chih-Ching Hu, Stony Brook, NY (US); Vincent Ip, Elmont, NY (US); Piero Sferlazzo, Marblehead, MA (US)

Correspondence Address: WOOD, HERRON & EVANS, LLP, 2700 CAREW TOWER, 441 VINE STREET, CINCINNATI, OH, 45202, US

(73) Assignee: Veeco Instruments Inc., Woodbury, NY (US)

(21) Appl. No.: 11/209,907

(22) Filed: Aug. 23, 2005

(51) Int. Cl. C23C 14/00

(52) U.S. Cl. 204/192.2

(57) ABSTRACT

An improved planetary sputter deposition method for sputter depositing an alloy on a substrate wherein the sputter deposited amount, or thickness, of a specific material of the alloy can be controlled so that different substrates can be provided with an alloy having a different composition, i.e. having different percentages of the same materials, thus, reducing the costs of stockpiling multiple alloy targets. The method generally includes providing a substrate and a plurality of targets with each of the plurality of targets being composed of one or more magnetic materials. The targets are sputtered, in sequence, to deposit each of the materials of the plurality of targets on the substrate to provide at least one laminate defining an alloy.

### FIELD OF THE INVENTION

The present invention relates to physical vapor deposition (PVD) for processing substrates like semiconductor wafers and data storage components and, more particularly, to using planetary sputter deposition methods for depositing a plurality of layers of magnetic material to form an alloy on such substrates.

### BACKGROUND OF THE INVENTION

Physical vapor deposition (PVD) modules or tools generally are used in the manufacture of sensor elements, for example, for giant magnetoresistance (GMR) and tunneling magnetoresistance (TMR) read/write heads for the data storage industry and similar devices. With PVD, typically thin layers or films of metal are stacked on a substrate using a sputtering system, which includes a vacuum chamber having a cathode including a source target. During the sputtering process, material is removed from the source target and subsequently deposited on the substrate to form one or more layers of a desired thickness. It is also desirable that the layers formed on the substrate have a highly uniform thickness. By way of example, a high level of thickness uniformity not exceeding a range of ±2% or higher may be desirable such as for heads for magnetic data storage and retrieval.

One class of conventional PVD modules or tools utilizes planetary sputter deposition which relies on motion providing both an arc shaped movement, i.e. sun rotation, in conjunction with simultaneous rotation, i.e. planetary rotation, of the substrate. This motion forms a compound pattern of movement generally providing a desirable thickness uniformity. By way of example, to deposit an alloy on a substrate using planetary sputter deposition, a single alloyed sputter source of a desired composition may be situated about the periphery of the top of a cylindrical vacuum chamber. The substrate is placed in a fixture that constitutes part of an assembly with a rotary arm. The substrate fixture, which is at the end of the rotary arm, incorporates provisions to continuously rotate the substrate at relatively high speed during a deposition cycle. The radius of rotation is such that the center of the substrate is approximately aligned with the center of the sputter source to achieve the specified film parameters. As the substrate passes or loops by the alloyed sputter source, a layer of material defining the alloy is sputter deposited on the substrate. Multiple passes may be performed to obtain stacked layers.

The length of the sputter sources with planetary sputter deposition is usually 1.5 to 2.0 times the substrate diameter to assure good intrinsic thickness uniformity for the film deposited on the substrate. The required characteristics of the deposited film (e.g., uniformity and thickness control) are achieved by the control of the scanning motion of the spinning substrate under the sputter source. Notably, feature size reductions along with a desire to reduce overall production costs in the data storage and semiconductor industries has created a movement to improve upon methods of sputter depositing alloys on substrates while maintaining or improving control over the thickness and/or uniformity of the sputtered material.

One weakness of conventional sputter deposition tools and techniques includes an inability to mix layers, for example, of different magnetic material(s) at the atomic level when sequentially sputtering multiple target sources to provide an alloy on a substrate. This prevents the ability to control or manipulate the amount of sputtered material from sputter sources when it is desirable to alter the compositional make-up of the alloy. For example, concerning the current use of alloy targets to provide an alloy on a substrate, a different alloy sputter source must be provided when an alloy with a different composition, i.e. one having different percentages of the same materials, is desired for sputter depositing on a substrate. As such, this process presents significant cost to the manufacturer and, ultimately, the consumer.

What is needed, therefore, is an improved planetary sputter deposition method for sputter depositing an alloy on a substrate wherein the sputter deposited amount, or thickness, of a specific material(s) can be controlled so that different substrates can be provided with an alloy having a different composition, i.e. having different percentages of the same materials, such as to reduce the costs of stockpiling multiple alloy targets.

### SUMMARY OF THE INVENTION

In accordance with an embodiment of the invention, a method of sputter depositing an alloy on a substrate by planetary sputter deposition techniques includes providing a PVD module or tool having a generally circular vacuum chamber adapted for holding a plurality of source targets, with each target being composed of one or more materials that are magnetically permeable either individually or when alloyed together. The targets are selected based upon the alloy desired on the substrate. For example, for a two-component alloy, one might provide two sputter targets with one target including one magnetic component, e.g. cobalt, and the other target including the second magnetic component, e.g. iron. In another example, for a three-component alloy, one might provide two sputter targets with one target including one magnetic component, e.g. chromium, and the other target including an alloy of the remaining two magnetic components, e.g. a NiFe alloy, or one might provide three sputter targets with each target including a different magnetic material. Accordingly, each of the plurality of targets for forming the alloy includes a different magnetic material than the other.

Generally, each of the plurality of targets includes about 99% of one or more magnetic materials chosen from the elements of Groups 1-15 of the periodic table, such as from a transition metal, lithium, beryllium, boron, carbon, and/or bismuth. In another example, each of the plurality of targets includes no less than about 99.9% and, in yet another example, no less than about 99.99% of magnetic material chosen from Groups 1-15 of the periodic table, such as from a transition metal, lithium, beryllium, boron, carbon, and/or bismuth. The targets generally are spaced about the periphery of the chamber. The PVD module further includes a rotary arm provided with a substrate carrier adapted for rotation about a first axis, i.e. planetary rotation. The rotary arm further is adapted for rotation about a second axis, i.e. sun rotation, to rotate the substrate thereabout.

During the sputtering process, a substrate is provided on the substrate carrier and rotated about the first axis with the rotary arm being rotated about the second axis to rotate the substrate therearound within the vacuum chamber. The center of the substrate is approximately aligned with the center of each target when the substrate sweeps by the target. As the substrate moves once around the chamber, i.e. performs one pass or loop by each target, the targets are sputtered, in sequence, on the substrate to deposit a layer of each of their magnetic material(s) to provide a laminate defining an alloy. Accordingly, each laminate is defined by one loop or pass by the plurality of targets providing the alloy on the substrate. A second pass or loop provides additional layers of sputtered magnetic materials to define a second laminate. This process may be repeated until a desired number of laminates having a desired alloy thickness is obtained. The thickness of the alloy, including the percent composition of each magnetic material thereof, generally is dependent upon the use of the coated substrate.

The deposited thickness of each layer of the laminate may be controlled, using planetary sputter deposition techniques, to a minimum layer thickness of about 0.1 angstrom (Å) and up to no greater than about 6 Å by adjusting the substrate sweeping velocity at fixed target power or vice versa, i.e. by adjusting the target power at fixed substrate sweeping velocity, thus, allowing for the layers of a laminate to mix at the atomic level. The thickness uniformity of the layers is maintained by velocity profiling and by rotation of the substrate.

Accordingly, the thickness of each layer includes a fraction of a mono-atomic layer made possible by planetary sputter deposition allowing for uniform mixing of the layers in the laminate. Each laminate is homogeneous, and each subsequent laminate is continuous with the adjacent laminate to form the alloy. Consequently, conventional stacking of layers is avoided and the sputter deposited amount, or thickness, of each layer of magnetic material(s) may be controlled or adjusted so that different substrates can be provided with an alloy having a different composition, i.e. having different percentages or amounts of the same materials using the same targets. The percent composition of magnetic material of the alloy, e.g. the sputtered material from a target composed of a single magnetic element, may be determined generally by dividing the total amount or total thickness of the sputtered material by the total thickness of the alloy, then multiplying by 100. As should be understood, if alloyed targets are sputtered, the percent of a specific material of the sputtered alloy should be taken into consideration when calculating the total percent composition of the alloy on the substrate.

In addition, with this method, the substrate typically is provided with a seed layer prior to sputtering the plurality of targets that form the alloy. As is understood in the art, the seed layer provides a foundation to firmly adhere the alloy to the substrate and provide a material microstructure base to enhance the alloy microstructure texture. This seed layer may be sputtered on the substrate within the chamber prior to sputtering of the first target source for providing the alloy portion of the substrate. As such, one or more additional targets may be provided in the chamber. In addition, a capping layer typically is sputtered on the substrate after sputtering, in sequence, the plurality of targets on the seed layer. As is understood in the art, the capping layer provides a protective covering for the alloy, for example, such as from corrosion due to prolonged exposure to the atmosphere. Again, one or more additional targets may be provided in the chamber for depositing the capping layer or one or more of the same targets that are used for depositing the seed layer may be utilized. Each of the targets used to provide the seed and capping layers also may be composed of one or more magnetic materials. Additionally, both the seed layer and capping layer may be sputtered by the same method used for the alloy.

Accordingly, the method of the present invention overcomes the performance limitations of current planetary sputter deposition tools and techniques and overcomes the cost disadvantages, for example, of having to stockpile sputter sources of a different alloy composition, i.e. having different percentages of the same materials.

These and other objects and advantages of the present invention shall become more apparent from the accompanying drawings and description thereof.

### BRIEF DESCRIPTION OF THE DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is a schematic top view of the inside of a vacuum chamber of a processing apparatus illustrating the method of the present invention;

FIG. 2 is a schematic elevational view of a source target and substrate within the vacuum chamber of the apparatus of FIG. 1;

FIG. 3 is a cross-sectional view of a coated substrate showing the seed layer, laminates defining the alloy, and capping layer as provided in accordance with the method of the present invention;

FIG. 4 is a chart illustrating the normalized magnetization of cobalt iron alloys, as prepared according to the method of the present invention, as a function of cobalt concentration;

FIG. 5 is a chart illustrating the compositional dependence of the pinning field of spin valves having a single pinned layer sputter deposited from a cobalt iron alloy target and of spin valves having 1, 2, 3, and 4 Å thick laminates of cobalt and iron with a total laminates or alloy thickness of about 25 Å.

### DETAILED DESCRIPTION OF SPECIFIC EMBODIMENTS

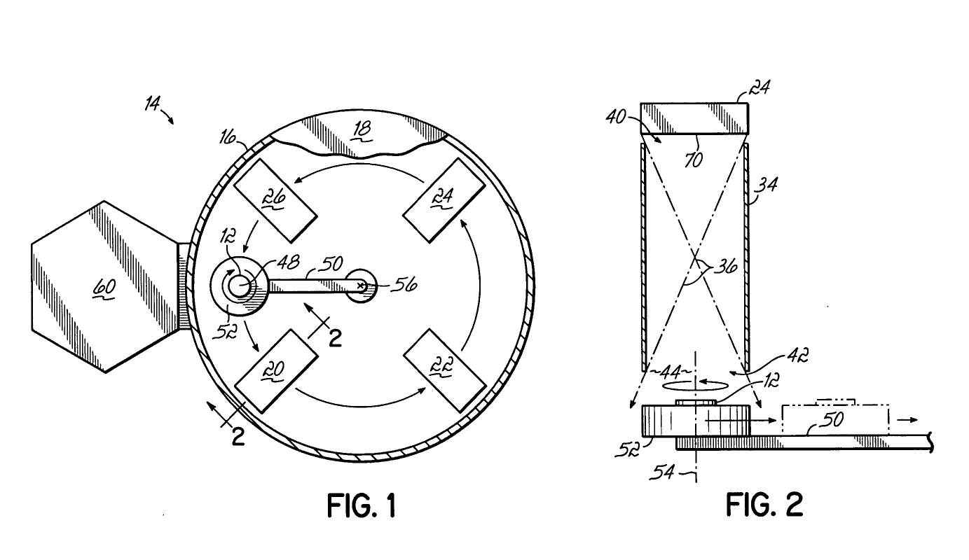

In accordance with an embodiment of the invention, as best shown in FIGS. 1-3, a method of sputter depositing an alloy 10 on a substrate 12 by planetary sputter deposition techniques includes providing a PVD module, or apparatus 14, having a vacuum chamber 16 and a chamber lid 18 (shown in partial) defining an evacuable or controlled atmosphere volume. The vacuum chamber 16 is provided with four targets 20, 22, 24 and 26. However, it is contemplated that the chamber 16 may hold up to about ten targets or more. The Nexus PVD-10 planetary process module available from Veeco Instruments, Inc. of Woodbury, N.Y., which is adapted to hold up to ten source targets, is one suitable type apparatus 14 for sputter depositing the alloy 10 on the substrate 12 in accordance with the method of the present invention. In addition, U.S. Pat. No. 5,795,448, which is hereby incorporated by reference herein in its entirety, describes the general operation of planetary process modules or devices. Although, planetary process modules and the operation thereof are understood in the art, apparatus 14 will be discussed herein in conjunction with the method of the invention.

As further shown in FIGS. 1-3, the targets 20, 22, 24, 26 generally are spaced about the periphery of the chamber 16 typically mounted to the chamber lid 18. Two of the targets 20, 22 are provided for sputter depositing both a seed and a capping layer 30 and 32 on the substrate 12 while the remaining two targets 24, 26 are provided for sputter depositing the alloy 10 therebetween. As is understood in the art, the seed layer 30 provides a foundation to firmly adhere the alloy 10 to the substrate 12. As is also understood in the art, the capping layer 32 provides a protective covering for the alloy 10, for example, such as from corrosion due to prolonged exposure to the atmosphere. It should be understood by one skilled in the art that more or less source targets 20, 22, 24, 26 may be provided depending upon the materials desired to be sputtered for the seed layer 30, capping layer 32, and/or the alloy 10.

In one example, each of the plurality of targets 24, 26 for providing the alloy 10 includes no less than about 99% of magnetic material. In another example, each of the targets 24, 26 includes no less than about 99.9% of magnetic material. In yet another example, each of the plurality of targets 24, 26 includes no less than about 99.99% of magnetic material. The magnetic material for these targets 24, 26 may be chosen from the elements of Groups 1-15 of the periodic table. In another example, the magnetic material may be chosen from a transition metal, i.e. the elements of Groups 3-12 of the periodic table, lithium, beryllium, boron, carbon, and bismuth. In yet another example, the magnetic material may be chosen from manganese, iron, cobalt, nickel, and copper. In still another example, the magnetic material may be chosen from cobalt and iron.

A chimney 34 is associated with each sputter source 20, 22, 24, 26 for confining the sputtered material as represented by arrows 36. Each chimney 34 (only one shown) includes opposing openings 40 and 42 with the source target 24 being provided adjacent the top opening 40 and the bottom opening 42 defining a deposition zone 44. The substrate 12 is adapted to sweep, as explained below, by each deposition zone 44 so that the confronting surface 48 of the substrate 12 is exposed to deposition fluxes 36 that accumulate as a layer or film.

The apparatus 14 further includes a rotary arm 50 provided with a substrate carrier 52 adapted for rotation about a first axis 54, i.e. planetary rotation. The rotary arm 50 further is adapted for rotation about a second axis 56, i.e. sun rotation, to rotate the substrate 12 thereabout. Although only one arm 50 is shown, a person of ordinary skill in the art will appreciate that multiple arms similar to arm 50 may be arranged in a hub and spoke arrangement for use in moving multiple substrates through the deposition zones 44.

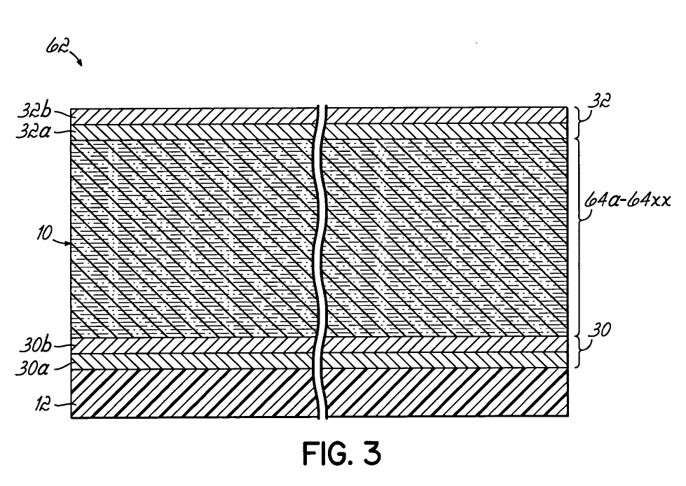

With further reference to FIGS. 1-3, the vacuum chamber 16 may be accessed through a substrate load/unload port 60 that normally is isolated therefrom. The load/unload port 60 is adapted for providing substrates 12 to, and removing coated substrates 62 (see FIG. 3) from, the substrate carrier 52 within the chamber 16 such as by way of a transfer robot (not shown) or other means known in the art.

As the substrate 12 moves once around the chamber 16, i.e. performs one pass or loop by targets 24, 26, the targets 24, 26 are sputtered, in sequence, on the substrate 12 to deposit a layer of a desired thickness of each of their magnetic material(s). Accordingly, after one loop or pass by targets 24, 26, the layers have mixed to define a single laminate 64a (see FIG. 3). A second pass or loop provides additional layers of each of the magnetic materials to define a second laminate and so on, for example, for fifty total passes to provide laminates 64a-64xx. The thickness of each layer of the laminates 64a-64xx includes a fraction of a mono-atomic layer made possible by planetary sputter deposition techniques, as further discussed below, that allows for uniform mixing of these layers in each of the laminates 64a-64xx. Therefore, each laminate 64a-64xx is homogeneous, with each laminate 64a-64xx being continuous with each adjacent laminate to form the alloy 10 on the substrate 12. It should be understood that one laminate or a plurality of laminates may be provided to define the alloy 10.

The number of targets 24, 26, and choice of magnetic materials, is selected based upon the alloy 10 desired on the substrate 12. For example, for sputter depositing a two-component alloy, e.g. a cobalt (Co) iron (Fe) alloy, on the substrate 12, one could provide two sputter targets with one target including one component, e.g. cobalt, and the other target including the second component, e.g. iron. Therefore, each element or magnetic material of the targets 24, 26 for forming the alloy 10 includes a different element or magnetic material than the other. It should be understood that the sputter deposited alloy 10 may involve more than two elements or magnetic materials, e.g. a three component alloy, thus, requiring either additional source targets or one of the targets 24, 26 to be composed of an alloy. By way of example, to sputter deposit a three-component alloy 10 of NiFeCr onto substrate 12, target 24 may include a nickel iron (NiFe) alloy with target 26 being composed of chromium (Cr).

As indicated above, with this method, the substrate 12 generally is provided with seed layer 30 (See FIG. 3). This seed layer 30 may be sputtered on the substrate 12 within the chamber 16 prior to sputtering of the target sources 24, 26 for providing the alloy 10 on the substrate 12. In addition, capping layer 32 (See FIG. 3) typically is sputtered on the substrate 12 after sputtering, in sequence, the plurality of targets 24, 26 on the substrate 12to provide the alloy 10. Coating of the substrate 12 with the seed and capping layer 30, 32 is further discussed below.

Each of the targets 20, 22 used to provide the seed and capping layers 30, 32 also may be composed of one or more magnetic materials. The number of targets 20, 22, and choice of magnetic material(s), similarly may be chosen based upon the desired materials for the seed and capping layers 30, 32. For example, for sputter depositing a two-component seed or capping layer 30, 32, for example, of tantalum and copper, on the substrate 12, one could provide two sputter targets with one target including tantalum and the other target including copper. As such, each element of the targets 20, 22 for forming the seed layer 30 is a different element than the other with the same holding true for the capping layer 32.

In one example, each of the targets 20, 22 for providing the seed and capping layers 30, 32 includes no less than about 99% of magnetic material. In another example, each of the targets 20, 22 includes no less than about 99.9% of magnetic material. In yet another example, each of the targets 20, 22 includes no less than about 99.999% of magnetic material. The magnetic material may be chosen from the elements of Groups 1-15 of the periodic table. In another example, the magnetic material may be chosen from a transition metal, i.e. any element of Groups 3-12 of the periodic table, lithium, beryllium, boron, carbon, or bismuth. In yet another example, the magnetic material may be chosen from tantalum and copper. In contrast to formation of the laminate(s) 64a-64xx, the sputter deposited layers 30a, 30b, 32a, 32b of the seed and capping layers 30, 32 generally are sputter deposited to cause stacking rather than mixing. To cause this stacking, each layer 30a, 30b, 32a, 32b of the seed and capping layers 30, 32 includes a thickness greater than about 6 Å.

A control system (not shown) orchestrates the operation of the apparatus 14. More specifically, the speed of the rotational (or planetary motion) and the angular velocity (or sun rotation) of the substrate carrier 52, and the deposition from the source targets 20, 22, 24, 26 are controlled by the control system, which has a construction understood by persons of ordinary skill in the art. In planetary sputter depositions, the substrate 12 typically spins at about 300 rpm about the first axis 54 while rotating at about 0.1 to about 7 rpm about the center of the deposition chamber, i.e. about the second axis 56, as it sweeps by individual targets 20, 22, 24, 26. However, it should be understood that the planetary and sun rotational speeds, respectively, may be less than or greater than 300 rpm and less than about 0.1 rpm and greater than about 7 rpm. The deposited thickness at any point on the substrate 10, therefore, depends on its dwell time beneath the source target 20, 22, 24, 26 and also on its trajectory by the target surface 70. Due to the non-uniform nature of the spatial distribution of a sputtered species, approximately in Gaussian form, substrate rotation about the second axis 56 at a constant velocity is not sufficient for a uniform deposition. Therefore, a modulation on the substrate rotation is required, and more specifically, the rotation velocity needs to be profiled so that the integral of the sputtered flux 36 over the trajectory of each point on the substrate 12 will be almost the same to ensure a uniform film thickness distribution across the substrate 12.

For a normalized film or layer thickness contour map on a 6-inch substrate for depositions in a 10-target deposition system using a constant velocity, the film is thicker at the center of the substrate and becomes thinner with increasing radial distance. This is consistent with the perception that the substrate 12 edge spends more time in an outer portion of the target 20, 22, 24, 26 where the sputter flux 36 is relatively low. Consequently, a 2-step symmetrical velocity profile may be utilized wherein the substrate 12 is adjusted to travel slower when it first enters the deposition zone 44 to allow for longer dwell time for more deposition, and then sped up to a desired or normal velocity.

To optimize a velocity profile, certain chamber 16 characteristic dimensions need to be known including the distance from the chamber center to the target center and the target chimney length and width. From these dimensions, the half angle of the chimney that extends to the chamber center can be determined. This sets an angular limit for the deposition zone 44. To prevent exposure to the sputter flux 36 prior to the deposition, the substrate 12 needs to be positioned outside the deposition zone 44, i.e. greater than about 16° or less than about −16° with reference to the target centerline. In another example, the starting position is typically set at about −20°, where the substrate 12 begins to assume the velocity profile, and for a 2-step velocity profile the offset is set at about 10°. An optimization of the film thickness uniformity is, therefore, a process of adjusting the velocity ratio to balance the exposure or dwell time of different portions along the radius of the substrate 12. Depending upon the requirement, up to 5 steps of the velocity profile can be employed.

The thickness uniformity can be evaluated by x-ray fluorescence, ellipsometry, or sheet resistance map of typically 49 points over the substrate surface. One additional feature that needs to be noticed is the evolution of the thickness profile, which changes from convex shapes with thicker film to concave shapes with thinner film at the center.

After the optimization of the deposition uniformity, the deposition rate can be calibrated. Typically two to three offset rotational velocity values are selected, for example, 0.5, 1 and 2 rpm, at a fixed change of rotational velocity value. A linear regression of the measured thickness in Å/sweep, typically 10-20 sweeps used for rate calibration depositions to achieve a comfortable level of thickness determination, versus 1/offset rotational velocity can be used to determine the deposition rate from which the required offset value for specified layer thickness can be determined. With increasing target erosion, optimization and rate recalibration may be required to ensure the best performance.

Accordingly, the deposited thickness of each layer of the laminates 64a-64xx in this method may be controlled down to a minimum layer thickness of about 0.1 Å by adjusting the substrate sweeping velocity at fixed target power or vice versa, i.e. by adjusting the target power at fixed substrate sweeping velocity, thus, allowing for the layers of a laminate to be uniformly mixed at the atomic level. The thickness of each layer includes a fraction of a mono-atomic layer made possible by planetary sputter deposition that allows for uniform mixing of the layers in each laminate 64a-64xx. Therefore, each laminate 64a-64xx is homogeneous, and each subsequent laminate is continuous with the adjacent laminate to form the alloy 10. Conventional stacking of layers is avoided and the sputter deposited amount, or thickness, of each layer may be controlled or adjusted so that different substrates 12 can be provided with an alloy having a different composition, i.e. having different percentages or amounts of the same materials using the same targets 24, 26.

In one example, each laminate 64a-64xx includes a thickness of no less than about 0.2 Å and no greater than about 6 Å of the magnetic materials of the plurality of targets 24, 26 which define the alloy 10. In another example, each laminate 64a-64xx includes a thickness of no less than about 0.2 Å and no greater than about 5 Å. It should be understood that the percent composition of magnetic material of the alloy 10, e.g. of the sputtered material from target 24 if composed of a single magnetic element, may be determined generally by dividing the total amount, i.e. total thickness, of the sputtered material by the total amount, i.e. total thickness, of the sputtered material deposited on the substrate 12 that forms the alloy 10, then multiplying by 100. As should be further understood, if alloyed targets are sputtered, this alloy composition needs to be considered, for example, when determining the percentage of one of the sputtered alloy materials in the alloy 10.

The thickness uniformity of the layers is maintained by velocity profiling and by rotation of the substrate, as explained above. In one example, uniform thickness deviation of the sputter deposited material is from no less than about 0.4% and no greater than about 0.6%.

A non-limiting example in accordance with the method of the present invention of sputter depositing an alloy 10, i.e. a cobalt iron alloy, on substrate 12 for use as a spin valve is hereby presented. With further reference to FIGS. 1-3, substrate 12 is loaded on the substrate carrier 52 at the load/unload port 60. The substrate 12 may be composed of any material suitable for the purpose(s) of the coated substrate 62. In this example, the substrate 12 is a silicon wafer and is 6 inches in diameter. It should be understood that the substrate 12 may be smaller or larger and/or of a different shape. Within the chamber 16, the substrate 12 is rotated at a desired speed about the first axis 54, such as at about 300 rpm, with the rotary arm 50 being rotated about the second axis 56 at specified or optimized angular velocities, as discussed above, to rotate the substrate 12 therearound within the vacuum chamber 16.

The source targets 24, 26 include a cobalt target 24 and an iron target 26 for forming the cobalt iron alloy, and a copper target 20 and a tantalum target 22 for forming both the seed and capping layers 30, 32. In one example, the magnetic material of targets 24, 26, respectively, includes pure cobalt and pure iron or no less than about 99% of cobalt and iron. In another example, targets 24, 26 include no less than about 99.9% of cobalt and iron respectively. In yet another example, targets 24, 26 include no less than about 99.99% of cobalt and iron respectively. The target size is about 13.5 inches by 6 inches. The source targets 20, 22, 24, 26 are arranged generally symmetrically about the second axis 56, which typically coincides with a vertical centerline of the chamber lid 18. The center of the substrate 12 is approximately aligned with the center of each target 20, 22, 24, 26 when the substrate 12 sweeps by the deposition zone 44 of each target 20, 22, 24, 26.

As is generally understood in the art, a magnetron (not shown) is positioned behind each source target 20, 22, 24, 26 to provide a magnetic field at the front target surface 70 of the sputtering target 20, 22, 24, 26. The sputtering target 20, 22, 24, 26 is connected to an electrical power supply (not shown) which, when energized, generates an electric field inside the vacuum chamber 16. The vacuum chamber 16 is evacuated and then filled at a low pressure with a suitable inert gas, such as argon. The electric field generates a plasma discharge in the inert gas adjacent to the sputtering target 20, 22, 24, 26. The magnetron supplies a magnetic field that confines and shapes the resulting plasma near the front target surface 70. Positively-charged ions from the plasma are accelerated toward the negatively-biased sputtering target 20, 22, 24, 26, where the ions bombard the front target surface 70 with sufficient energy to sputter atoms of the target material. The flux 36 of sputtered target material travels ballistically toward the substrate 12 positioned in opposition to the sputtering target 20, 22, 24, 26 inside the vacuum chamber 16.

Accordingly, as the substrate 12 moves once around the chamber 16, i.e. performs one pass or loop by each target 20, 22, 24, 26, the targets are sputtered, in sequence, at a desired target power (generally a fixed target power from about 50-2000 watts) as discussed above, to deposit a layer of a desired thickness of each of the elements on the substrate 12. The seed layer 30 is sputter deposited on the substrate 12 first and includes a sputter deposited layer 30a of tantalum then a layer 30b of copper. The copper layer 30b is stacked on the tantalum layer 30a, i.e. forms a distinct layer thereon, with the sputtered layer 30a of tantalum being about 50 Å thick and the copper layer 30b being about 30 Å thick. It is generally understood in the art that stacking begins to occur at about 6 Å.

Next, the cobalt and iron targets 24, 26 are sputtered in sequence on the substrate 12, i.e. on the seed layer 30, to provide a cobalt layer and an iron layer that mix to define laminate 64a. A second pass or loop provides an additional layer of each of these elements to define a second laminate 64b. Specifically, 0.7 Å of cobalt and 0.3 Å of iron are sputter deposited on the substrate per pass to provide a laminate thickness of about 1.0 Å. For the purposes of this example, each layer of each laminate 64a-64xx maintains a constant thickness. However, it should be understood that the layer thickness does not necessarily need to be constant. This process of sputter depositing laminates may be repeated until a desired number of laminates having a desired alloy thickness is obtained. In this example, this process is repeated fifty times to provide fifty laminates 64a-64xx with a total laminates thickness of 50 Å. The thickness of the alloy 10 generally is dependent upon the use of the coated substrate 62. The percent composition or make-up of the alloy 10 is about 70% cobalt and about 30% iron.

After the desired number of laminates 64a-64xx having the desired thickness has been deposited, the capping layer 32 is sputter deposited on the substrate 12, i.e. on the last laminate 64xx. This capping layer 32 includes a first layer 32a of copper then a layer 32b of tantalum. The sputtered layer 32a of copper is about 30 Å thick and the tantalum layer 32b is about 50 Å thick. The copper layer 32a is stacked on the last laminate 64xx, i.e. forms a distinct layer thereon, with the tantalum layer 32b being stacked on the copper layer 32a again forming a distinct layer thereon. The coated substrate 62 then is removed from the vacuum chamber 16 at the load/unload port 60.

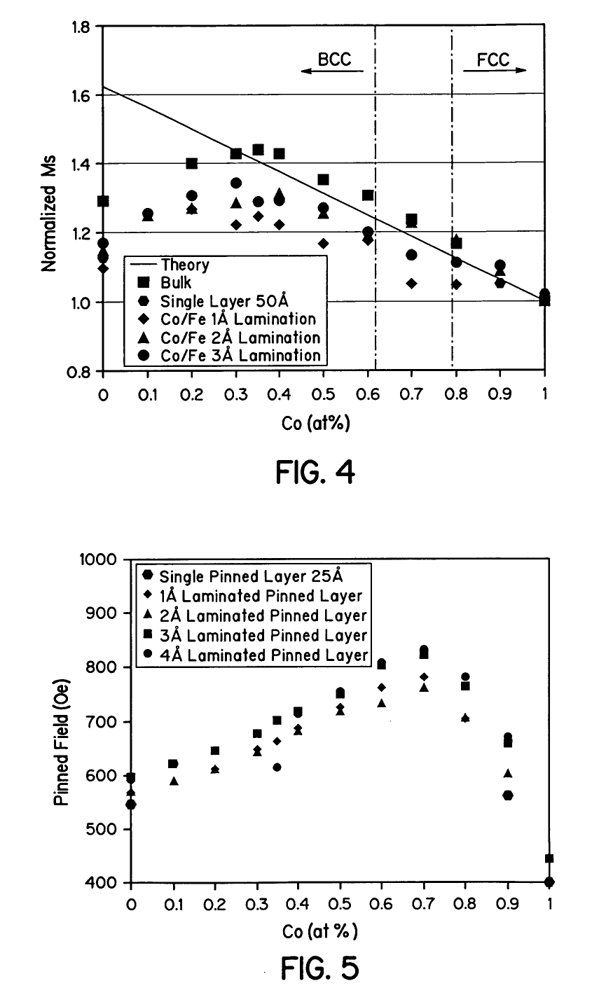

FIG. 4 is a chart illustrating normalized magnetization as a function of cobalt concentration. Specifically, a vibration sample magnetometer (VSM) was used to measure the magnetic moment of sputter deposited pure cobalt, sputter deposited pure iron, and cobalt iron alloy samples of bulk material. In addition, VSM was used to measure the magnetic moment of each of 1, 2, and 3 Å layer laminates of cobalt and iron having a total laminates or alloy thickness of about 50 Å, which was provided according to the methods of the present invention, and of a sputter deposited cobalt iron alloy (90:10 alloy) of a 50 Å thick single layer laminate on a substrate, which was deposited via an alloyed sputter source of 90% cobalt and 10% iron. The measurements were normalized with pure cobalt and compared. The magnetization of the 1, 2, and 3 Å thick laminates defining the 50 Å thick alloy substantially matched those of the pure Co, Fe and Co₉₀Fe₁₀ alloy films. As such, the compositional dependence of the laminates reconstructs the well-known Slater-Pauling curve of the bulk cobalt iron alloys indicating that the laminates are homogeneous.

The functionality of cobalt iron laminations was further demonstrated through application by forming the pinned layer, i.e. the alloy layer, in exchange biased spin-valve films for advanced recording read heads. As shown in FIG. 5, the compositional dependence of the pinning field for 1, 2, 3, and 4 Å thick laminates of cobalt and iron having a total laminates or alloy thickness of about 25 Å, provided according to the methods of the present invention, delineated closely those of the single pinned layer (25 Å) sputter deposited from cobalt iron alloy targets. Based upon FIG. 5, the best pin in field for the spin valve included an alloy, or pinned layer, of about 70% cobalt and about 30% iron.

In addition, it should be understood that the method of the present invention can be extended, as mentioned above, to include sputter deposition of three component alloys, for example, NiFeCo, CoFeCu, and NiFeCr, and four, five, etc. component alloys. It is further contemplated that non-magnetic components, or elements, may be sputtered or mixed, such as by the methods described above, with magnetic elements to provide, for example, alloys of AlOCu, etc., which may be either magnetically permeable or non-magnetic.

Accordingly, the method of the present invention overcomes the performance limitations of planetary sputter deposition which use alloyed sputter sources and overcomes the cost disadvantages of having to stockpile sputter sources of a different alloy composition, i.e. having different percentages of the same materials.

While the present invention has been illustrated by a description of various embodiments and while these embodiments have been described in considerable detail, it is not the intention of the applicant to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicant's general inventive concept.

What is claimed is:

1. A method of sputter depositing an alloy on a substrate, comprising:
sputtering, in sequence, a plurality of targets on a substrate, each of the plurality of targets being composed of material that is magnetically permeable, the material of each of the plurality of targets being different than the other; and
depositing on the substrate a laminate including the material from each of the plurality of targets to define an alloy.

2. The method of claim 1 wherein the laminate includes a thickness of no less than about 0.2 Å and no greater than about 6 Å.

3. The method of claim 1 wherein the laminate includes a thickness of no less than about 0.2 Å and no greater than about 5 Å.

4. The method of claim 1 further comprising repeating sputtering, in sequence, the plurality of targets on the substrate, and wherein depositing on the substrate a laminate including material from each of the plurality of sputtered targets comprises depositing on the substrate a plurality of laminates, each of the plurality of laminates including the material from each of the plurality of targets, the plurality of laminates defining the alloy.

5. The method of claim 4 wherein each of the plurality of laminates defining the alloy includes a thickness of no less than about 0.2 Å and no greater than about 6 Å.

6. The method of claim 1 wherein the material of each of the plurality of targets includes no less than about 99% purity of magnetic material chosen from the elements of Groups 1-15 of the periodic table.

7. The method of claim 1 wherein the material from each of the plurality of targets includes no less than about 99.9% purity of magnetic material chosen from the elements of Groups 1-15 of the periodic table.

8. The method of claim 1 wherein sputtering, in sequence, a plurality of targets on a substrate comprises sputtering, in sequence, at least a first and second target, the first target being composed of cobalt and the second target being composed of iron, and wherein depositing on the substrate a laminate including the material from each of the plurality of sputtered targets comprises depositing on the substrate the laminate including cobalt and iron from the first and second target, the laminate defining a cobalt iron alloy.

9. The method of claim 8 wherein the cobalt iron alloy comprises about 70% cobalt and about 30% iron to provide a maximum spin valve pinning field.

10. A method of sputter depositing an alloy on a substrate, comprising:
rotating a substrate on a substrate carrier about a first axis and rotating a rotary arm about a second axis to rotate the substrate therearound within a vacuum chamber;
sputtering, in sequence, a plurality of targets within the vacuum chamber on the substrate, each of the plurality of targets being composed of material that is magnetically permeable, the material of each of the plurality of targets being different than the other; and
depositing on the substrate a laminate including the material from each of the plurality of targets to define an alloy.

11. The method of claim 10 further including sputter depositing a seed layer on the substrate prior to sputtering, in sequence, the plurality of targets within the vacuum chamber on the substrate, and further including sputter depositing a capping layer on the laminate after depositing on the substrate the laminate including the material from each of the plurality of targets.

12. The method of claim 10 wherein the laminate defining the alloy includes a thickness of no less than about 0.2 Å and no greater than about 6 Å.

13. The method of claim 10 wherein the laminate defining the alloy includes a thickness of no less than about 0.2 Å and no greater than about 5 Å.

14. The method of claim 10 further comprising repeating sputtering, in sequence, the plurality of targets within the vacuum chamber on the substrate, and wherein depositing on the substrate a laminate including the material from each of the plurality of targets comprises depositing on the substrate a plurality of laminates, each of the plurality of laminates including the material from each of the plurality of targets, the plurality of laminates defining the alloy.

15. The method of claim 14 further including sputter depositing a seed layer on the substrate prior to sputtering, in sequence, the plurality of targets within the vacuum chamber on the substrate, and further including sputter depositing a capping layer on the laminate after depositing on the substrate the plurality of laminates.

16. The method of claim 14 wherein each of the plurality of laminates defining the alloy includes a thickness of no less than about 0.2 Å and no greater than about 6 Å.

17. A method of sputter depositing an alloy on a substrate, comprising:
sputtering, in sequence, a plurality of targets on a substrate, each of the plurality of targets being composed of material chosen from the elements of Groups 1-15 of the periodic table, the material of each of the plurality of targets being different than the other; and
depositing on the substrate a laminate including the material from each of the plurality of targets to define an alloy.

18. The method of claim 17 further comprising repeating sputtering, in sequence, the plurality of targets on the substrate, and wherein depositing on the substrate a laminate including the material from each of the plurality of targets comprises depositing on the substrate a plurality of laminates, each of the plurality of laminates including the material from each of the plurality of targets, the plurality of laminates defining the alloy, each of the plurality of laminates defining the alloy further including a thickness of no less than about 0.2 Å and no greater than about 6 Å.

19. The method of claim 17 wherein the material from each of the plurality of targets includes no less than about 99% of magnetic material chosen from the elements of Groups 1-15 of the periodic table.

20. The method of claim 17 wherein the material from each of the plurality of targets includes no less than about 99.9% of magnetic material chosen from the elements of Groups 1-15 of the periodic table.
